(19) United States
(12) Patent Application Publication
(10) Pub. No.: US 2024/0194585 A1
(43) Pub. Date: Jun. 13, 2024

(54) SUPER VIA WITH SIDEWALL SPACER

(71) Applicant: INTERNATIONAL BUSINESS MACHINES CORPORATION, ARMONK, NY (US)

(72) Inventors: Ruilong Xie, NIskayuna, NY (US); Nicholas Anthony Lanzillo, Wynantskill, NY (US); Koichi Motoyama, Clifton Park, NY (US); Lawrence A. Clevenger, Saratoga Springs, NY (US); Hosadurga Shobha, Niskayuna, NY (US); Huai Huang, Clifton Park, NY (US); Chih-Chao Yang, Glenmont, NY (US)

(21) Appl. No.: 18/065,120

(22) Filed: Dec. 13, 2022

(51) Int. Cl. H01L 23/522; H01L 21/768; H01L 23/528

(52) U.S. Cl. CPC H01L 23/5226; H01L 21/76816; H01L 21/76834; H01L 21/76883; H01L 23/5283

(57) ABSTRACT

A semiconductor device includes a first metallization layer; a second metallization layer formed on the first metallization layer; a third metallization layer formed on the second metallization layer; a super via extending from the first metallization layer to the third metallization layer; and an inner spacer layer formed on sidewalls of the super via from the second metallization layer to the first metallization layer.

### BACKGROUND

The present disclosure relates to the semiconductor device fields. In particular, the present disclosure relates to vias or super vias that electrically connect metal lines with more than one metal level gap.

Generally, semiconductor devices can include a plurality of circuits which form an integrated circuit fabricated on a substrate. A complex network of signal paths can be routed to connect the circuit elements distributed on the surface of the substrate. Efficient routing of these signals can include the formation of multilevel or multilayered schemes (e.g., single or dual damascene wiring structures) during the back-end-of-line (BEOL) phase of manufacturing. Within an interconnect structure, conductive vias can run perpendicular to the substrate and conductive lines can run parallel to the substrate.

To enable better interconnect scaling and avoid minimum area limitation of metal wirings, super via is used to connect metal lines with skipping at least one metal level. Current fabrication methods for such super vias require forming a very deep trench to enable the resulting via formed in the trench to establish electrical connection between the metal lines with more than 1 level of gap. Such deep via etch is challenging. Sometimes the etch process may results CD blow-up, adequate lateral spacing must be maintained between the super via and adjacent interconnects to prevent shorting between the super via and adjacent structures.

Current fabrication methods used to form such a super via trench necessarily result in the trench having tapered side walls. More specifically, the side walls are angled inwardly from the top of the trench to the bottom of the trench such that the width of the top of the trench is greater than the width of the bottom of the trench. Moreover, the deeper the trench, the larger the difference between the width of the top of the trench and the width of the bottom of the trench. Smaller device dimensions and tighter pitches between adjacent structures may increase the probability of electrical shorting between vias (or super vias) and adjacent metal lines.

### SUMMARY

Embodiments of the present disclosure include a semiconductor device. The semiconductor device includes a first metallization layer; a second metallization layer formed on the first metallization layer; a third metallization layer formed on the second metallization layer; a super via extending from the first metallization layer to the third metallization layer; and an inner spacer layer formed on sidewalls of the super via from the second metallization layer to the first metallization layer.

Embodiments of the present disclosure include a method of manufacturing a semiconductor device. The method includes forming an Mx−1 layer; forming a Vx−1 layer on the Mx−1 layer; forming a Mx layer on the Vx−1 layer; etching a trench in the Mx layer and the Vx−1 layer; forming an inner spacer layer on sidewalls of an interlayer dielectric layer in the Mx layer and the Vx−1 layer; forming a sacrificial layer in the Mx layer and the Vx−1 layer between the inner spacer layer; forming a Vx layer on the Mx layer; forming a Mx+1 layer on the Vx layer; removing the sacrificial layer; and forming a super via that extends from the Vx layer to the Mx−1 layer.

The above summary is not intended to describe each illustrated embodiment or every implementation of the present disclosure.

### BRIEF DESCRIPTION OF THE DRAWINGS

The drawings included in the present disclosure are incorporated into, and form part of, the specification. They illustrate embodiments of the present disclosure and, along with the description, serve to explain the principles of the disclosure. The drawings are only illustrative of typical embodiments and do not limit the disclosure.

FIG. 1 illustrates a cross-sectional schematic of a semiconductor device at an intermediate stage of the manufacturing process, in accordance with embodiments of the present disclosure.

FIG. 2 illustrates a cross-sectional schematic of the semiconductor device of FIG. 1 at a subsequent stage of the manufacturing process, in accordance with embodiments of the present disclosure.

FIG. 3 illustrates a cross-sectional schematic of the semiconductor device of FIG. 2 at a subsequent stage of the manufacturing process, in accordance with embodiments of the present disclosure.

FIG. 4 illustrates a cross-sectional schematic of the semiconductor device of FIG. 3 at a subsequent stage of the manufacturing process, in accordance with embodiments of the present disclosure.

FIG. 5 illustrates a cross-sectional schematic of the semiconductor device of FIG. 4 at a subsequent stage of the manufacturing process, in accordance with embodiments of the present disclosure.

FIG. 6 illustrates a cross-sectional schematic of the semiconductor device of FIG. 5 at a subsequent stage of the manufacturing process, in accordance with embodiments of the present disclosure.

FIG. 7 illustrates a cross-sectional schematic of the semiconductor device of FIG. 6 at a subsequent stage of the manufacturing process, in accordance with embodiments of the present disclosure.

FIG. 8 illustrates a cross-sectional schematic of the semiconductor device of FIG. 7 at a subsequent stage of the manufacturing process, in accordance with embodiments of the present disclosure.

FIG. 9 illustrates a cross-sectional schematic of the semiconductor device of FIG. 8 at a subsequent stage of the manufacturing process, in accordance with embodiments of the present disclosure.

FIG. 10 illustrates a cross-sectional schematic of the semiconductor device of FIG. 9 at a subsequent stage of the manufacturing process, in accordance with embodiments of the present disclosure.

### DETAILED DESCRIPTION

The present disclosure relates to the semiconductor device fields. In particular, the present disclosure relates to vias and super vias (or skip vias) that electrically connect transistors with buried power rails and backside power distribution networks. While the present disclosure is not necessarily limited to such applications, various aspects of the disclosure may be appreciated through a discussion of various examples using this context.

Various embodiments of the present disclosure are described herein with reference to the related drawings. Alternative embodiments can be devised without departing from the scope of the present disclosure. It is noted that various connections and positional relationships (e.g., over, below, adjacent, etc.) are set forth between elements in the following description and in the drawings. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements. It should be noted, the term “selective to,” such as, for example, “a first element selective to a second element,” means that a first element can be etched, and the second element can act as an etch stop.

In general, the various processes used to form a micro-chip that will be packaged into an IC fall into four general categories, namely, film deposition, removal/etching, semiconductor doping and patterning/lithography.

Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Another deposition technology is plasma enhanced chemical vapor deposition (PECVD), which is a process which uses the energy within the plasma to induce reactions at the wafer surface that would otherwise require higher temperatures associated with conventional CVD. Energetic ion bombardment during PECVD deposition can also improve the film's electrical and mechanical properties.

Removal/etching is any process that removes material from the wafer. Examples include etch processes (either wet or dry), chemical-mechanical planarization (CMP), and the like. One example of a removal process is ion beam etching (IBE). In general, IBE (or milling) refers to a dry plasma etch method which utilizes a remote broad beam ion/plasma source to remove substrate material by physical inert gas and/or chemical reactive gas means. Like other dry plasma etch techniques, IBE has benefits such as etch rate, anisotropy, selectivity, uniformity, aspect ratio, and minimization of substrate damage. Another example of a dry removal process is reactive ion etching (RIE). In general, RIE uses chemically reactive plasma to remove material deposited on wafers. With RIE the plasma is generated under low pressure (vacuum) by an electromagnetic field. High-energy ions from the RIE plasma attack the wafer surface and react with it to remove material.

Semiconductor doping is the modification of electrical properties by selectively adding impurities, for example, transistor sources and drains, generally by diffusion and/or by ion implantation. These doping processes may be followed by furnace annealing or by rapid thermal annealing (“RTA”). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device.

Semiconductor lithography is the formation of three-dimensional relief images or patterns on the semiconductor substrate for subsequent transfer of the pattern to the substrate. In semiconductor lithography, the patterns are formed by a light sensitive polymer called a photo-resist. To build the complex structures that make up a transistor and the many wires that connect the millions of transistors of a circuit, lithography and etch pattern transfer steps are repeated multiple times. Each pattern being printed on the wafer is aligned to the previously formed patterns and gradually the conductors, insulators and selectively doped regions are built up to form the final device.

Turning now to an overview of technologies that are more specifically relevant to aspects of the present disclosure, as mentioned above, geometrical constraints dictate, to some extent, the sizing and spacing of contact trenches and resulting vias that electrically connect transistors to buried power rails and backside power distribution networks. More specifically, the width of the bottom of the trench must be made sufficiently large to enable the establishment of a reasonable contact area with the interconnect underneath. However, this minimum width of the bottom of the trench may result in a width of the top of the trench that is too large relative to the spacing between adjacent structures, such as transistors or contact pads. Alternatively, in order to maintain adequate spacing at the top of the trench, the width at the bottom of the trench may be made too small to establish reliable contact area with the interconnect underneath. Developments in semiconductor fabrication, including trends toward closer spacing of transistors, make it more likely that the width at the bottom of the trench will be too small than that the width at the top of the trench will be made too large.

The embodiments described herein provide structures and methods for forming a semiconductor device having a skip via, also referred to herein as a super via, in a subtractive etch back-end-of-line (BEOL) integration scheme. A skip via in accordance with the embodiments described herein can provide a connection between conductive lines of respective metallization levels in a manner that bypasses an intermediate metallization level. More specifically, a skip via SVx can connect an Mx line to an Mx+2 line, thereby bypassing the X+1 level and the corresponding Mₓ₊₁ line. The embodiments described herein can eliminate possible electrical shorting between the super via and the adjacent metal lines with the inclusion of a dielectric sidewall spacer prior to the formation of the super via.

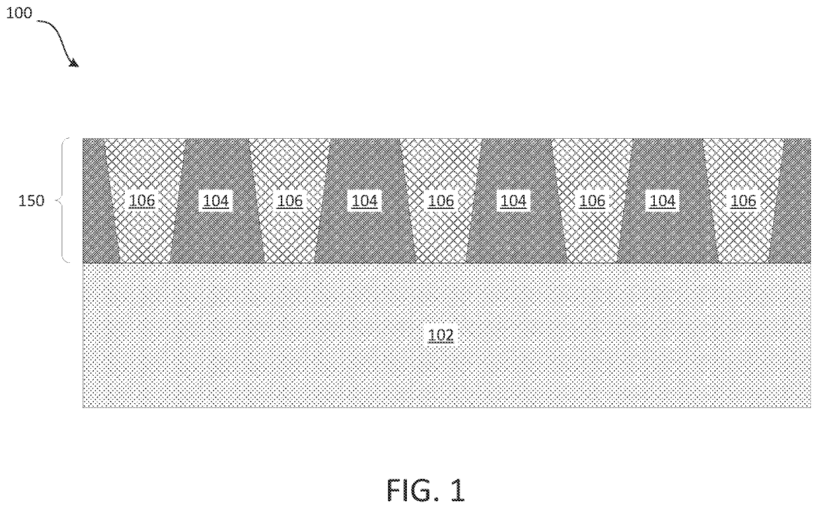

Referring now to the figure and initially to FIG. 1, this figure illustrates a cross-sectional schematic of a semiconductor device 100 at an intermediate stage of the manufacturing process, in accordance with embodiments of the present disclosure. As shown in FIG. 1, a substrate 102 or underlying device is provided as a base layer upon which the various metallization (Mx) layers are formed. In accordance with some embodiments of the present disclosure, the layer of substrate 102 material may bedevices such as transistors, capacitors, resistors, diodes or interconnects such as lower BEOL levels using conventional Cu damascene process.

As also shown in FIG. 1, the semiconductor device 100 is shown includes a first metallization level 150. The first metallization level 150 (e.g., Mₓ₋₁) includes a first interlayer dielectric (ILD) layer 104. It should be appreciated that the first ILD layer 104 may include any suitable ILD material. Trenches are formed in the first ILD layer 104 by any suitable material removal process known to one of skill in the art. After the trenches are formed, a first metallization 106 or conductive line is formed in the first metallization level 150. The first metallization 106 can include any suitable conductive material(s) in accordance with the embodiments described herein. Examples of suitable conductive materials that can be used to form the first metallization 106 include, but are not limited to, copper (Cu), ruthenium (Ru), cobalt (Co), etc. In certain embodiments, after the formation of the first metallization 106, a suitable material removal process may be performed (e.g., CMP) to planarize the upper surfaces of the first ILD layer 104 and the first metallization 106.

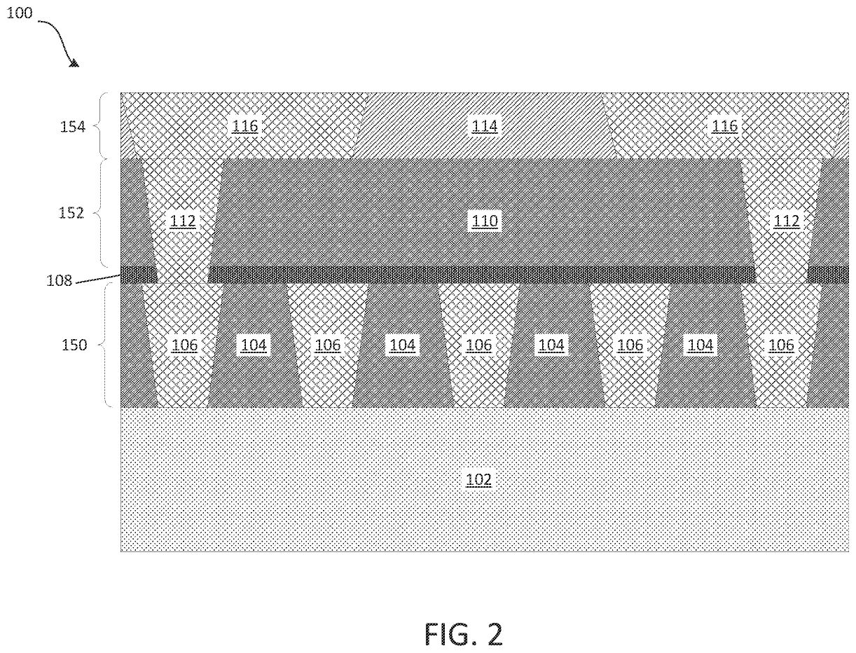

Referring now to FIG. 2, this figure illustrates a cross-sectional schematic of the semiconductor device 100 of FIG. 1 at a subsequent stage of the manufacturing process, in accordance with embodiments of the present disclosure. As shown in FIG. 2, a first cap layer 108 (or Mₓ₋₁ cap layer) is formed on the first metallization level 150. In certain embodiments, the first cap layer 108 may include, for example, a nitrogen-doped silicon carbide material, AlOₓ, AlNₓ, etc. Then a suitable material removal process (e.g., etching) is performed to create openings in the first cap layer 108 that expose one or more of the portions of the first metallization 106 (i.e., in the example of FIG. 2, the rightmost and leftmost first metallizations 106 are exposed).

Then, as shown in FIG. 2, a second ILD layer 110 is formed on the first cap layer 108. A suitable material removal process is used to form trenches in the second ILD layer 110. The material removal process for the second ILD layer 110 may be the same or different as the process used for the first ILD layer 104. Then, second metallizations 112 (e.g., also referred to as metal vias of, for example, a Vₓ₋₁ layer) are formed in the trenches of the second ILD layer 110. It should be appreciated that in certain embodiments, the first cap layer 108 and the second ILD layer 110 may be formed prior to forming the trenches and the second metallizations 112, and etching may be performed on both the second ILD layer 110 and the first cap layer 108 in the same material removal process. In certain embodiments, after the formation of the second metallizations 112, a suitable material removal process may be performed (e.g., CMP) to planarize the upper surfaces of the second ILD layer 110 and the second metallizations 112 (or vias). In certain embodiments, the second ILD layer 110 and the second metallizations 112 are part of a second metallization level 152 or Vₓ₋₁ layer.

Then, as shown in FIG. 2, a third ILD layer 114 is formed on the second ILD layer 110 and the second metallizations 112. It should be appreciated that the material of the first ILD layer 104, the second ILD layer 110 and the third ILD layer 114 may be the same materials or different materials. A suitable material removal process is used to form trenches in the third ILD layer 114. The material removal process for the third ILD layer 114 may be the same or different as the process used for the first ILD layer 104 and the second ILD layer 110. Then, third metallizations 116 (e.g., metal lines of a Mx layer) are formed in the trenches of the third ILD layer 114. In certain embodiments, the third ILD layer 114 and the third metallizations 116 are part of a third metallization level 154 or Mx layer. In certain embodiments, after the formation of the third metallizations 116, a suitable material removal process may be performed (e.g., CMP) to planarize the upper surfaces of the third ILD layer 114 and the third metallizations 116. Thus, at this stage of the manufacturing process, the Mₓ₋₁, Vₓ₋₁ and Mₓ levels are formed, where Mx is the middle line that will be skipped by the subsequently formed skip via (or super via), as described in detail below.

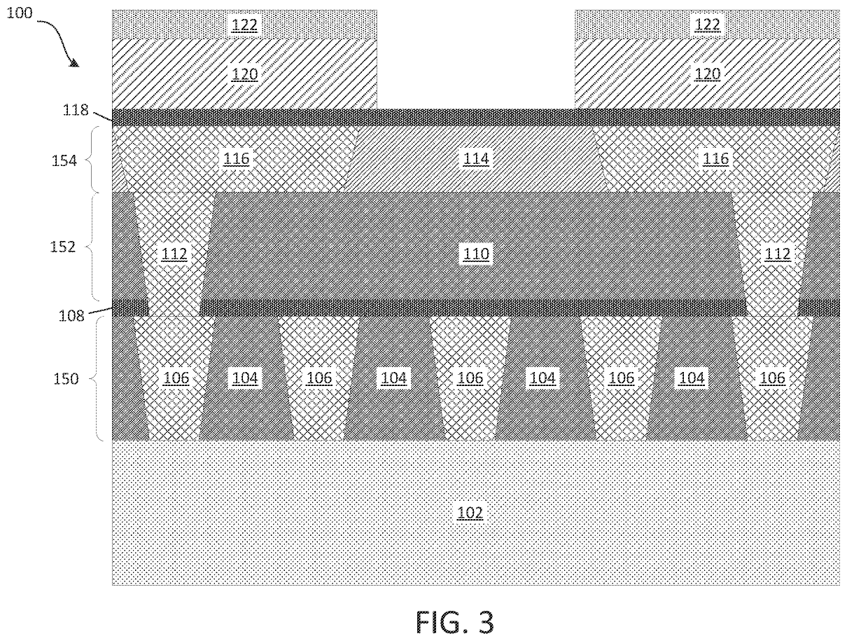

Referring now to FIG. 3, this figure illustrates a cross-sectional schematic of the semiconductor device 100 of FIG. 2 at a subsequent stage of the manufacturing process, in accordance with embodiments of the present disclosure. As shown in FIG. 3, a second cap layer 118 is formed on the upper surfaces of the third ILD layer 114 and the third metallizations 116. It should be appreciated that the material of the second cap layer 118 may be the same material or a different material than the material of the first cap layer 108. Then, an organic planarization (OPL) layer 120 is formed on the second cap layer 118. The OPL layer 120 may comprise any suitable material OPL material known to one skilled in the art. An anti-reflecting layer 122 is then formed on the OPL layer 120. In certain examples, the anti-reflecting layer 122 may include a silicon containing anti-reflecting coating (or SiARC). An opening is created in both the anti-reflecting layer 122 and the OPL layer 120 to expose the second cap layer 118, and this opening corresponds to a location above the third ILD layer 114 and between the portions of the third metallizations 116.

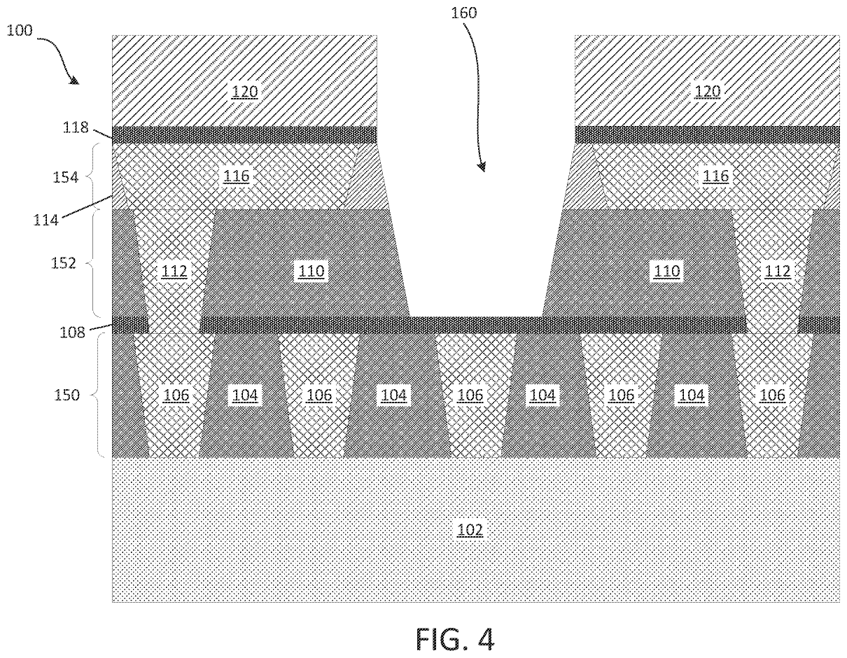

Referring now to FIG. 4, this figure illustrates a cross-sectional schematic of the semiconductor device 100 of FIG. 3 at a subsequent stage of the manufacturing process, in accordance with embodiments of the present disclosure. As shown in FIG. 4, a lower portion of a super via opening 160 is etched by removing portions of the second cap layer 118, the third ILD layer 114 and the second ILD layer 110 that are not covered (or masked) by the OPL layer 120. In certain embodiments, the anti-reflecting layer 122 is also removed at this stage. In the present embodiments, the etching of these layers to form the trench for the super via is simplified due to the low aspect ratio and in that the materials to be etched are relatively easy to etch. In other words, relative to related art techniques of forming super via trenches, in the present embodiments, the formation of the opening 160 is not a very deep etch (i.e., relative to if etching was performed all the way from the Mₓ₊₁ layer to the Mₓ₋₁ layer) because only lower portion of the super via is being etched at this stage.

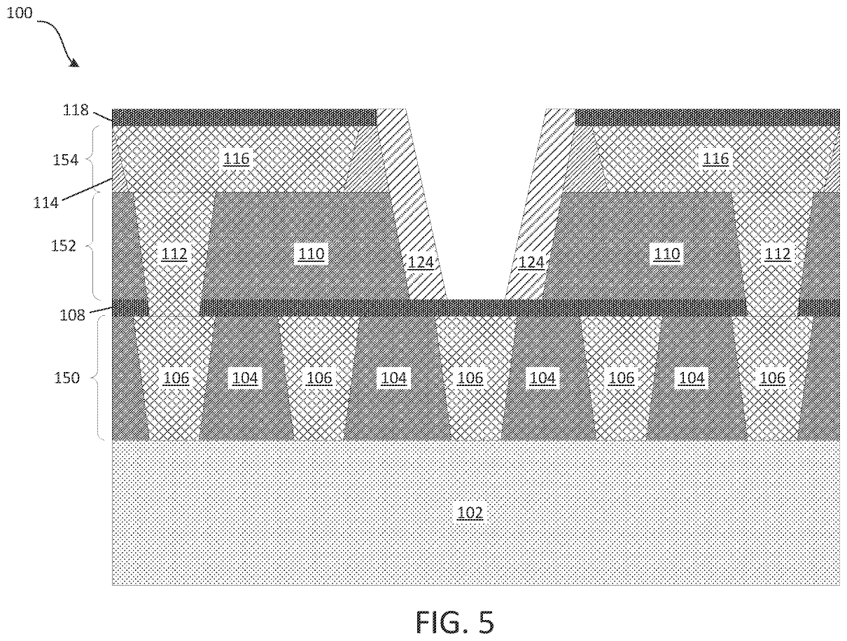

FIG. 5 illustrates a cross-sectional schematic of the semiconductor device 100 of FIG. 4 at a subsequent stage of the manufacturing process, in accordance with embodiments of the present disclosure. As shown in FIG. 5, an inner spacer 124 (or dielectric spacer layer) is deposited on the sidewalls of the second ILD layer 110, the sidewalls of the third ILD layer 114 and the sidewalls of the second cap layer 118. The inner spacer 124 has a function to protect the sidewalls of the low-K dielectric materials of the second ILD layer 110 and the third ILD layer 114. As will be described in further detail below, during subsequent removal of the sacrificial layer between the inner spacers 124 there is a wet etching process, and this wet etching process could damage the sidewalls of the low-K dielectric ILD layers if not for the presence of the inner spacers 124. In certain embodiments, a top surface of the inner spacer layer 124 is coplanar with the top surface of the second cap layer 118.

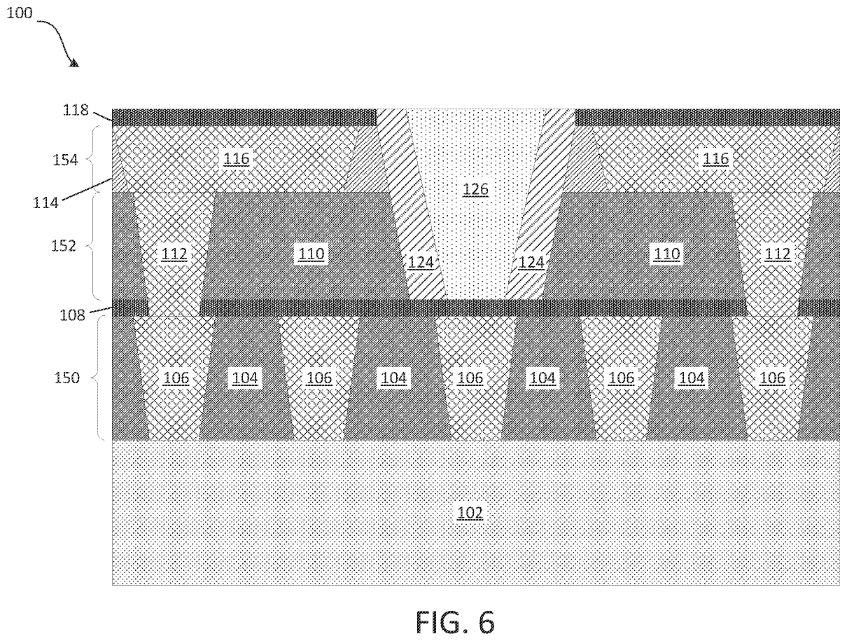

Referring now to FIG. 6, this figure illustrates a cross-sectional schematic of the semiconductor device 100 of FIG. 5 at a subsequent stage of the manufacturing process, in accordance with embodiments of the present disclosure. As shown in FIG. 6, a sacrificial layer 126 is formed in the space between the inner spacers 124. The sacrificial layer 126 may comprise, for example, a-SiGe, a-Si, SeGe or TiO₂, etc. Therefore, at this stage of the manufacturing process, the trench that will be used for the super via is filled with a dummy material (or sacrificial material) that will be later removed. In certain embodiments, after the formation of the sacrificial layer 126, a suitable material removal process may be performed (e.g., CMP) to planarize the upper surfaces of the semiconductor device 100.

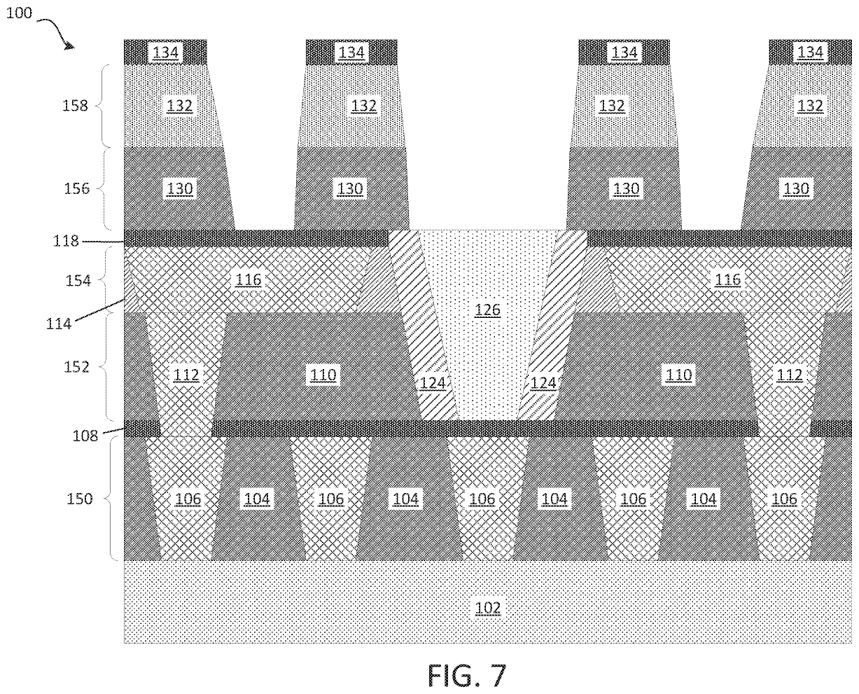

Referring now to FIG. 7, this figure illustrates a cross-sectional schematic of the semiconductor device of FIG. 6 at a subsequent stage of the manufacturing process, in accordance with embodiments of the present disclosure. As shown in FIG. 7, a fourth ILD layer 130 is formed on the second cap layer 118. The fourth ILD layer 130 is part of a fourth metallization level 156 (e.g., a Vx layer). Then, a fifth ILD layer 132 is formed on the fourth ILD layer 130. The fifth ILD layer 132 is part of a fifth metallization level 158 (e.g., a Mₓ₊₁ layer). Then, a mask layer 134 is formed on the fifth ILD layer 132 to pattern the metal lines and vias for the fourth metallization level 156 and the fifth metallization level 158. As shown in FIG. 7, a suitable material removal process is used to form trenches in the fourth ILD layer 130 and the fifth ILD layer 132 using the mask layer 134 as a patterning mask. It should be noted that with material removal process steps, the depth of the trenches are not as deep as a traditional super via because the etching stops on the sacrificial layer 126. Thus, the aspect ratio of the resultant trenches are lower due to the lower etching depth (i.e., relative to a full super via etch).

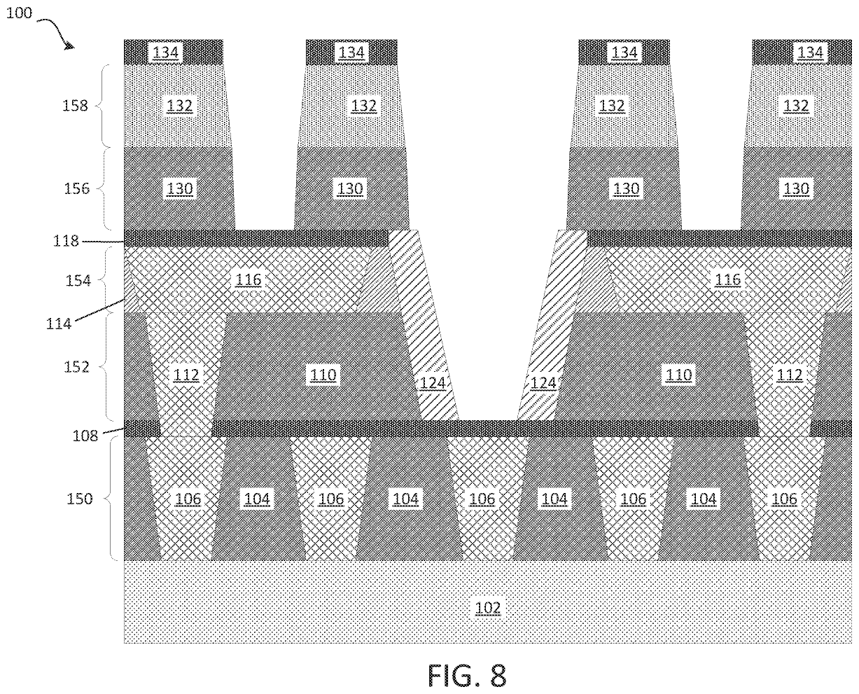

Referring now to FIG. 8, this figure illustrates a cross-sectional schematic of the semiconductor device of FIG. 7 at a subsequent stage of the manufacturing process, in accordance with embodiments of the present disclosure. As shown in FIG. 8, a suitable material removal process is used to selectively remove the dummy super via material of the sacrificial layer 126, which exposes the first cap layer 108 between the inner spacers 124.

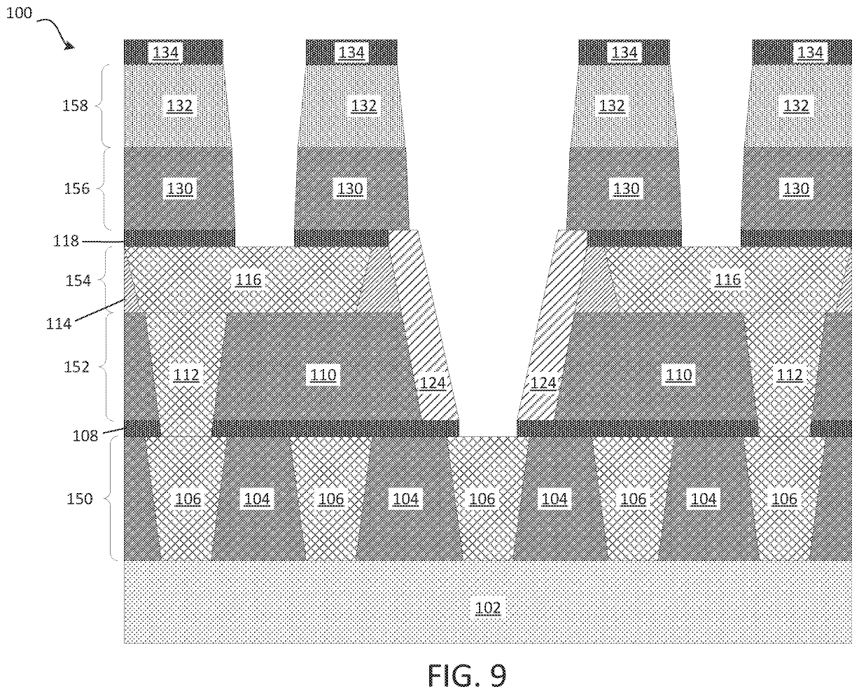

Referring now to FIG. 9, this figure illustrates a cross-sectional schematic of the semiconductor device of FIG. 8 at a subsequent stage of the manufacturing process, in accordance with embodiments of the present disclosure. As shown in FIG. 9, a suitable material removal process is used to selectively remove the exposed portion of the first cap layer 108 between the inner spacers 124, which exposes the first metallization 106. Also, the same (or different) material removal process is used to selectively remove the exposed portions of the second cap layer 118, which exposes the third metallizations 116.

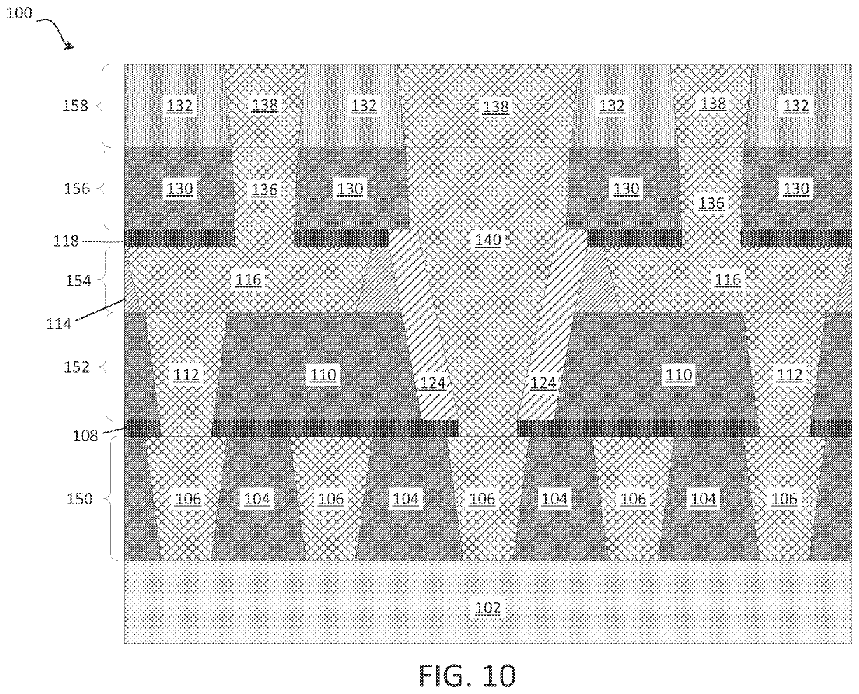

Referring now to FIG. 10, this figure illustrates a cross-sectional schematic of the semiconductor device of FIG. 9 at a subsequent stage of the manufacturing process, in accordance with embodiments of the present disclosure. As shown in FIG. 10, a suitable material deposition process is performed to deposit a super via 140, fourth metallizations 136 (e.g., Vx level vias) and fifth metallizations 138 (e.g., Mₓ₊₁ level metal lines). It should be noted that there is no metal liner between top and bottom portions of the super via 140, and there are no problems with achieving a minimum contact area of the Mx layer (i.e., the metal of the super via 140 at the third metallization level 154). Also, the super via 140 patterning process is simplified relative to related super via formation methods (e.g., no additional mask is required). In certain embodiments, the super via 140 has a stepped profile at an interface between the Vx layer and the Mx layer, where it gets wider at the fourth metallization level 156.

Thus, in FIGS. 1-10, the operations form various back end of line (BEOL) structures. In accordance with at least one embodiment of the present disclosure, the performance of these manufacturing operations can include the performance of any number of sub-operations to form the BEOL structures (e.g., vias and metal lines). The processes and formation of such BEOL structures may be performed using known methods and techniques. The inner spacers 124 protect the second ILD layer 110 and the third ILD layer 114 during the removal of the sacrificial layer 126, which may help to minimize any electrical shorting between the super via 140 and the third metallizations 116 (e.g., the Mx level metal lines).

In addition to embodiments described above, other embodiments having fewer operational steps, more operational steps, or different operational steps are contemplated. Also, some embodiments may perform some or all of the above operational steps in a different order. Furthermore, multiple operations may occur at the same time or as an internal part of a larger process.

In the foregoing, reference is made to various embodiments. It should be understood, however, that this disclosure is not limited to the specifically described embodiments. Instead, any combination of the described features and elements, whether related to different embodiments or not, is contemplated to implement and practice this disclosure. Many modifications and variations may be apparent to those of ordinary skill in the art without departing from the scope and spirit of the described embodiments. Furthermore, although embodiments of this disclosure may achieve advantages over other possible solutions or over the prior art, whether or not a particular advantage is achieved by a given embodiment is not limiting of this disclosure. Thus, the described aspects, features, embodiments, and advantages are merely illustrative and are not considered elements or limitations of the appended claims except where explicitly recited in a claim(s).

The terminology used herein is for the purpose of describing particular embodiments only and is not intended to be limiting of the various embodiments. As used herein, the singular forms “a,” “an,” and “the” are intended to include the plural forms as well, unless the context clearly indicates otherwise. It will be further understood that the terms “includes” and/or “including,” when used in this specification, specify the presence of the stated features, integers, steps, operations, elements, and/or components, but do not preclude the presence or addition of one or more other features, integers, steps, operations, elements, components, and/or groups thereof. In the previous detailed description of example embodiments of the various embodiments, reference was made to the accompanying drawings (where like numbers represent like elements), which form a part hereof, and in which is shown by way of illustration specific example embodiments in which the various embodiments may be practiced. These embodiments were described in sufficient detail to enable those skilled in the art to practice the embodiments, but other embodiments may be used, and logical, mechanical, electrical, and other changes may be made without departing from the scope of the various embodiments. In the previous description, numerous specific details were set forth to provide a thorough understanding the various embodiments. However, the various embodiments may be practiced without these specific details. In other instances, well-known circuits, structures, and techniques have not been shown in detail in order not to obscure embodiments.

As used herein, “a number of” when used with reference to items, means one or more items. For example, “a number of different types of networks” is one or more different types of networks.

When different reference numbers comprise a common number followed by differing letters (e.g., 100a, 100b, 100c) or punctuation followed by differing numbers (e.g., 100-1, 100-2, or 100.1, 100.2), use of the reference character only without the letter or following numbers (e.g., 100) may refer to the group of elements as a whole, any subset of the group, or an example specimen of the group.

Further, the phrase “at least one of,” when used with a list of items, means different combinations of one or more of the listed items can be used, and only one of each item in the list may be needed. In other words, “at least one of” means any combination of items and number of items may be used from the list, but not all of the items in the list are required. The item can be a particular object, a thing, or a category.

For example, without limitation, “at least one of item A, item B, or item C” may include item A, item A and item B, or item B. This example also may include item A, item B, and item C or item B and item C. Of course, any combinations of these items can be present. In some illustrative examples, “at least one of” can be, for example, without limitation, two of item A; one of item B; and ten of item C; four of item B and seven of item C; or other suitable combinations.

Different instances of the word “embodiment” as used within this specification do not necessarily refer to the same embodiment, but they may. Any data and data structures illustrated or described herein are examples only, and in other embodiments, different amounts of data, types of data, fields, numbers and types of fields, field names, numbers and types of rows, records, entries, or organizations of data may be used. In addition, any data may be combined with logic, so that a separate data structure may not be necessary. The previous detailed description is, therefore, not to be taken in a limiting sense.

The descriptions of the various embodiments of the present disclosure have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

Although the present invention has been described in terms of specific embodiments, it is anticipated that alterations and modification thereof will become apparent to one skilled in the art. Therefore, it is intended that the following claims be interpreted as covering all such alterations and modifications as fall within the true spirit and scope of the invention.

What is claimed is:

1. A semiconductor device, comprising:
a first metallization layer;
a second metallization layer formed on the first metallization layer;
a third metallization layer formed on the second metallization layer;
a super via extending from the first metallization layer to the third metallization layer; and
an inner spacer layer formed on sidewalls of the super via from the second metallization layer to the first metallization layer.

2. The semiconductor device of claim 1, wherein:
the super via has a stepped profile.

3. The semiconductor device of claim 1, further comprising a first cap layer formed between the first metallization layer and the inner spacer layer.

4. The semiconductor device of claim 1, further comprising:
a Vₓ₋₁ layer between the first metallization layer and the second metallization layer; and
a Vx layer between the third metallization layer and the second metallization layer.

5. The semiconductor device of claim 4, wherein:
the first metallization layer is a Mₓ₋₁ layer, the second metallization layer is a Mₓ layer, and the third metallization layer is a Mₓ₊₁ layer.

6. The semiconductor device of claim 5, wherein the super via includes portions of the Vₓ layer, the Mx layer and the Vₓ₋₁ layer.

7. The semiconductor device of claim 6, wherein the super via has a stepped profile at an interface between the Vₓ layer and the Mₓ layer.

8. The semiconductor device of claim 3, further comprising a second cap layer formed between the second metallization layer and the third metallization layer.

9. The semiconductor device of claim 1, wherein:
the inner spacer layer comprising a dielectric material, the inner spacer layer electrically isolating the super via from an interlayer dielectric layer.

10. The semiconductor device of claim 1, wherein the first metallization layer, the second metallization layer and the third metallization layer are part of a back end of line (BEOL) structure of the semiconductor device.

11. A method of making a semiconductor device, the method comprising:
forming an Mₓ₋₁ layer;
forming a Vₓ₋₁ layer on the Mₓ₋₁ layer;
forming a Mₓ layer on the Vₓ₋₁ layer;
etching a trench in the Mₓ layer and the Vₓ₋₁ layer;
forming an inner spacer layer on sidewalls of an interlayer dielectric layer in the Mₓ layer and the Vₓ₋₁ layer;
forming a sacrificial layer in the Mₓ layer and the Vₓ₋₁ layer between the inner spacer layer;
forming a Vₓ layer on the Mₓ layer;
forming a Mₓ₊₁ layer on the Vₓ layer;
removing the sacrificial layer; and
forming a super via that extends from the Vₓ layer to the Mₓ₋₁ layer.

12. The method of making a semiconductor device according to claim 11, wherein the super via has a stepped profile.

13. The method of making a semiconductor device according to claim 11, further comprising forming a first cap layer between the Mₓ₋₁ layer and the inner spacer layer.

14. The method of making a semiconductor device according to claim 13, further comprising forming an opening in the first cap layer to expose a portion of the Mₓ₋₁ layer.

15. The method of making a semiconductor device according to claim 13, further comprising forming a second cap layer between the Vₓ layer and the Mₓ₊₁ layer.

16. The method of making a semiconductor device according to claim 11, wherein the sacrificial layer includes at least one of a-SiGe, a-Si, SeGe or TiO₂.

17. The method of making a semiconductor device according to claim 11, wherein the super via has a stepped profile at an interface between the Vₓ layer and the Mₓ layer.

18. The method of making a semiconductor device according to claim 15, wherein a top surface of the inner spacer layer is coplanar with the top surface of the second cap layer.

19. The method of making a semiconductor device according to claim 11, wherein:
the inner spacer layer comprises a dielectric material, the inner spacer layer electrically isolating the super via from the interlayer dielectric layer.

20. The method of making a semiconductor device according to claim 11, wherein the Mₓ₋₁ layer, the Vₓ₋₁ layer, the Mₓ layer, the Vₓ layer and the Mₓ₊₁ layer are part of a back end of line (BEOL) structure of the semiconductor device.
